(19) United States
(12) Patent Application Publication
(10) Pub. No.: US 2009/0057903 A1
(43) Pub. Date: Mar. 5, 2009

(54) Semiconductor module, method for manufacturing semiconductor modules, semiconductor apparatus, method for manufacturing semiconductor apparatuses, and portable device

(76) Inventors: Yoshio OKAYAMA, Anpachi-gun (JP); Yasunori INOUE, Ogaki-shi (JP); Ryosuke USUI, Ichinomiya-shi (JP)

Correspondence Address: MCDERMOTT WILL & EMERY LLP, 600 13TH STREET, N.W., WASHINGTON, DC, 20005-3096, US

(21) Appl. No.: 12/078,311

(22) Filed: Mar. 28, 2008

(30) Foreign Application Priority Data
Mar. 29, 2007 (JP) 2007-089830
Jul. 20, 2007 (JP) 2007-190138

(51) Int. Cl. H01L 23/522; H01L 21/768; H01L 23/538; H01L 21/50

(52) U.S. Cl. 257/741; 438/618; 257/777; 438/109; 257/E23.142; 257/E21.575; 257/E23.169; 257/E21.499

(57) ABSTRACT

Cost is suppressed and a semiconductor module is made thinner. The semiconductor is of a structure where a semiconductor element is embedded in a recess formed in a wiring substrate. A substrate electrode provided around the recess and an element electrode are electrically connected through a wiring formed integrally with bumps.

### CROSS-REFERENCE TO RELATED APPLICATIONS

This application is based upon and claims the benefit of priority from the prior Japanese Patent Applications No. 2007-089830, filed on Mar. 29, 2007, and Japanese Patent Application No. 2007-190138, filed on Jul. 20, 2007, the entire contents of which are incorporated herein by reference.

### BACKGROUND OF THE INVENTION

1. Field of the Invention

The present invention relates to a semiconductor module that packages a wiring substrate and a semiconductor chip and a manufacturing method therefor. The present invention relates also to a semiconductor apparatus of stacked semiconductor packages, each semiconductor package including a wiring substrate and a semiconductor chip, and a manufacturing method therefor, and portable devices incorporating such a semiconductor apparatus.

2. Description of the Related Art

Portable electronic devices, such as mobile phones, PDAS, DVCs, and DSCs, are today gaining an increasing variety of functions. And to be accepted by the market, they have to be smaller in size and lighter in weight, and for that reason, there is a growing demand for highly-integrated system LSIs. On the other hand, these electronic devices are expected to be easier or handier to use, and therefore the LSIs used in those devices are required to be more functionally sophisticated and better performing. Thus the higher integration of LSI chips is causing increases in I/O count, which in turn generate demand for smaller and thinner packages. To satisfy both these requirements, it is strongly expected that semiconductor packages just right for the high board density packaging of semiconductor parts be developed.

For instance, a first conventional package structure is known in which a semiconductor chip is placed in a recess provided in a wiring substrate, with electrodes on the wiring substrate connected to electrodes on the semiconductor chip by wire bonding, for the purpose of realizing a thinner package.

Also, a second conventional package structure is known, in which a semiconductor chip is placed in a recess provided in a wiring substrate, with electrodes on the wiring substrate connected to electrodes on the semiconductor chip by rewiring.

For the first conventional package structure, wire bonding is used to electrically connect the electrodes on the wiring substrate to the electrodes on the semiconductor chip. Such a structure places limits on the attempts at thinning the package because the wire loop requires its own height. Also, since it is necessary to connect wire to every electrode provided on the wiring substrate and the semiconductor chip, cost will rise with the increase in the number of pins used.

With the second conventional package structure, too, the cost can rise because a rewiring must be formed by via processing with laser and plating to form a metallic film.

Thus, the problem with a semiconductor apparatus having a stack of conventional package structures is not only the difficulty of making it thinner but also increased cost of its fabrication.

### SUMMARY OF THE INVENTION

The present invention has been made in view of the foregoing problems, and a general purpose thereof is to provide a technology for making a thinner semiconductor module. An advantage of the present invention is to provide a technology for making a thinner semiconductor apparatus of stacked semiconductor modules while reducing the cost of fabrication thereof.

One embodiment of the present invention provides a semiconductor module. The semiconductor module comprises: a wiring substrate; a semiconductor element placed in a recess formed in the wiring substrate; a substrate electrode provided around the recess in the wiring substrate; an element electrode provided on the semiconductor element opposite to a bottom of the recess; and a wiring having a wiring layer integrally formed with a conductive bump for electrically connecting the substrate electrode to the element electrode. Here, the state of a wiring layer integrally formed with the conductive bump means a seamless connection of the bump and the wiring layer.

According to this embodiment, the element electrode provided on the semiconductor element embedded in the recess in the wiring substrate and the substrate electrode provided on the wiring substrate are electrically connected with each other by the bumps integrally formed with the wiring. The wiring, which does not require as much thickness as wire bonding, makes it possible to form a thinner semiconductor module. Also, the wiring works to reduce the manufacturing cost of the semiconductor module because the wiring can be formed by etching and heated press-bonding of a metal sheet without the use of laser processing or plating. Furthermore, the wiring layer integrally formed with the bumps can realize a semiconductor module that features low resistance and high reliability.

In a semiconductor module according to this embodiment, a material used for the wiring may be a rolled copper sheet. And the rolled copper sheet can raise the mechanical strength of the wiring. It also realizes a semiconductor module with even higher reliability.

In a semiconductor module according to the above-described embodiment, the height of the element electrode may be approximately equal to the height of the substrate electrode. In such an arrangement, the use of the bumps of nearly equal height permits the bonding between the substrate electrode and the bumps and between the element electrode and the bumps, thus improving the accuracy of electrode connection.

In a semiconductor module according to the above-described embodiment, an insulating resin that develops plastic flow under pressure may be provided between the wiring substrate and the wiring layer. Such an arrangement allows a heated press-bonding of the wiring to the wiring substrate through the medium of the insulating resin that develops plastic flow under pressure, thereby having the bumps penetrate the insulating layer to accomplish the bonding between the substrate electrode and the bump and between the element electrode and the bump.

Another embodiment of the present invention provides a method for manufacturing a semiconductor module. The method for manufacturing a semiconductor module includes: placing a semiconductor element into a recess provided in a wiring substrate; and electrically connecting a substrate electrode provided on a surface of the wiring substrate around the recess and an element electrode provided on a surface of the semiconductor element by use a wiring including a wiring layer integrally formed with conductive bumps corresponding respectively to the substrate electrodes and the element electrodes.

According to this embodiment, a thinner semiconductor module can be manufactured by electrically connecting the element electrode on a semiconductor element, which is embedded in a recess in the wiring substrate, and the substrate electrode on the wiring substrate by means of bumps provided integrally on the wiring. Also, the manufacturing cost of the semiconductor module can be reduced because the wiring can be formed by etching and heated press-bonding of a metal sheet without the use of laser processing or plating. Furthermore, the wiring layer integrally formed with the bumps can realize a semiconductor module that features low resistance and high reliability.

In the electrically connecting substrate electrode and element electrode by use of the wiring described in the above embodiment, the bumps included in the wiring may be connected respectively to the substrate electrodes and the element electrodes by press-bonding the wiring through an insulating layer that develops plastic flow under pressure. In this manner, the bonding between the substrate electrodes and the bumps and between the element electrodes and the bumps can be accomplished at low cost without the use of laser processing or plating.

Still another embodiment of the present invention provides a semiconductor apparatus having a plurality of semiconductor modules stacked together. At least one of the plurality of semiconductor modules comprises: a wiring substrate; a semiconductor element placed in a recess formed in the wiring substrate; a substrate electrode provided around the recess in the wiring substrate; an element electrode provided on the semiconductor element opposite to a bottom of the recess; and a wiring having a wiring layer integrally formed with a conductive bump for electrically connecting the substrate electrode to the element electrode. Here, the state of a wiring layer integrally formed with the conductive bump means a seamless connection of the bump and the wiring layer.

According to this embodiment, the element electrode provided on the semiconductor element embedded in the recess in the wiring substrate and the substrate electrode provided on the wiring substrate are electrically connected with each other by the bumps integrally formed with the wiring. The wiring, which does not require as much thickness as wire bonding, makes it possible to form a thinner semiconductor module. Also, the wiring works to reduce the manufacturing cost of the semiconductor module because the wiring can be formed by etching and heated press-bonding of a metal sheet without the use of laser processing or plating. Furthermore, the wiring layer integrally formed with the bumps can realize a semiconductor module that features low resistance and high reliability.

In a semiconductor apparatus, according to the above-described embodiment, which may have a pair of upper and lower semiconductor modules stacked on each other, the upper semiconductor module may have an external electrode formed under the wiring substrate, and the external electrode may be electrically connected to the wiring of the lower semiconductor module.

In each semiconductor module of the semiconductor apparatus according to the above-described embodiment, a material used for the wiring may be a rolled copper sheet. The rolled copper sheet can raise the mechanical strength of the wiring. It also realizes a semiconductor apparatus with even higher reliability.

In each semiconductor module of the semiconductor apparatus according to the above-described embodiment, the height of the element electrode may be approximately equal to the height of the substrate electrode. Thereby, the use of the bumps of nearly equal height permits the bonding between the substrate electrode and the bump and between the element electrode and the bump, thus improving the accuracy of electrode connection.

In each semiconductor module of the semiconductor apparatus according to the above-described embodiment, an insulating resin that develops plastic flow under pressure may be provided between the wiring substrate and the wiring layer. Such an arrangement allows a heated press-bonding of the wiring to the wiring substrate through the medium of the insulating resin that develops plastic flow under pressure, thereby having the bumps penetrate the insulating layer to accomplish the bonding between the substrate electrode and the bump and between the element electrode and the bump.

Still another embodiment of the present invention relates to a method for manufacturing a semiconductor apparatus. The method for manufacturing a semiconductor apparatus comprises: forming a semiconductor module; and stacking a plurality of semiconductor modules including the semiconductor module formed in the forming a semiconductor apparatus. The forming a semiconductor module includes: placing a semiconductor element into a recess provided in a wiring substrate; and electrically connecting substrate electrode provided on a surface of the wiring substrate around the recess and element electrode provided on a surface of the semiconductor element by use a wiring including a wiring layer integrally formed with conductive bumps corresponding respectively to the substrate electrode and the element electrode.

According to this embodiment, a semiconductor apparatus comprising thinner semiconductor modules stacked therein can be manufactured by electrically connecting the element electrode on a semiconductor element, which is embedded in a recess in the wiring substrate, and the substrate electrode on the wiring substrate by means of bumps provided integrally on the wiring. Also, the manufacturing cost of the semiconductor apparatus can be reduced because the wiring can be formed by etching and heated press-bonding of a metal sheet without the use of laser processing or plating. Furthermore, since the wiring layer and the bumps are integrally formed with each other, a semiconductor apparatus that features low resistance and high reliability is realized.

In the electrically connecting substrate electrode and element electrode by use of the wiring described in the above embodiment, the bumps included in the wiring may be connected respectively to the substrate electrode and the element electrode by press-bonding the wiring through an insulating layer that develops plastic flow under pressure. By implementing this embodiment, the bonding between the substrate electrode and the bump and between the element electrode and the bump can be accomplished at low cost without the use of laser processing or plating.

Still another embodiment of the present invention relates to a portable device. This portable device includes a semiconductor module according to any of the above-described embodiments. According to this embodiment, a smaller and thinner portable equipment can be produced at low cost.

It is to be noted that any arbitrary combinations or rearrangement of the aforementioned structural components and so forth are all effective as and encompassed by the embodiments of the present invention.

Moreover, this summary of the invention does not necessarily describe all necessary features so that the invention may also be sub-combination of these described features.

### BRIEF DESCRIPTION OF THE DRAWINGS

Embodiments will now be described by way of examples only, with reference to the accompanying drawings which are meant to be exemplary, not limiting, and wherein like elements are numbered alike in several Figures in which:

FIG. 1 is a schematic cross-sectional view illustrating a structure of a semiconductor module according to a first embodiment of the present invention;

FIG. 2 is a cross-sectional view showing a method for manufacturing a semiconductor module according to a first embodiment of the present invention;

FIG. 3 is a schematic cross-sectional view showing a structure of a semiconductor apparatus according to a second embodiment of the present invention;

FIG. 4 is a cross-sectional view for showing a method for manufacturing a semiconductor apparatus according to a second embodiment of the present invention;

FIG. 5 is a cross-sectional view of a semiconductor module used in the manufacturing of a semiconductor apparatus;

FIG. 6 illustrates a structure of a mobile phone provided with a semiconductor apparatus according to a second embodiment of the present invention; and

FIG. 7 is a partial cross-sectional view (cross-sectional view of a first casing) of a mobile phone shown in FIG. 6.

### DETAILED DESCRIPTION OF THE INVENTION

The invention will now be described by reference to the preferred embodiments. This does not intend to limit the scope of the present invention, but to exemplify the invention.

Hereinbelow, the embodiments will be described with reference to the accompanying drawings.

### FIRST EMBODIMENT

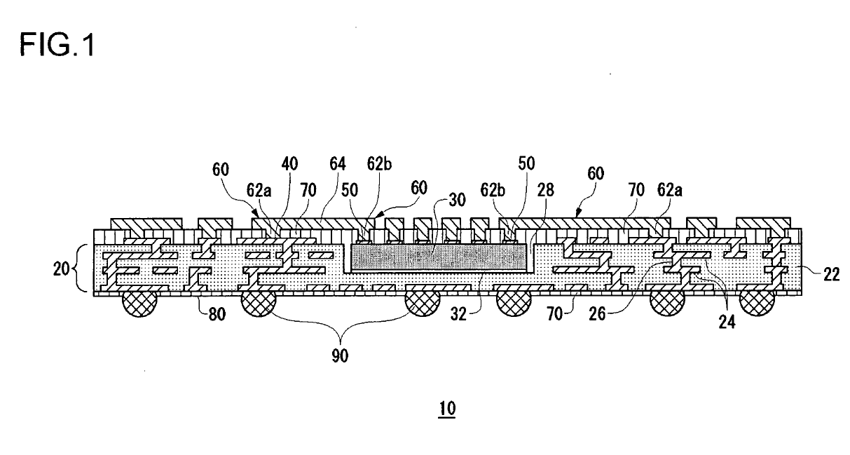

FIG. 1 is a schematic cross-sectional view illustrating a structure of a semiconductor module 10 according to a first embodiment of the present invention. The semiconductor module 10 according to the first embodiment includes, as principal components, a wiring substrate 20, a semiconductor element 30, substrate electrodes 40, element electrodes 50, and a wiring 60.

The wiring substrate 20 has a multilayer wiring structure with a plurality of wiring layers 24 stacked through the medium of an insulating layer 22. The insulating layer 22 may be made of, for example, a melamine derivative, such as BT resin, or a thermosetting resin, such as liquid-crystal polymer, epoxy resin, polyphenylene ether (PPE) resin, polyimide resin, fluorine resin, phenol resin or polyamide bismaleimide. The wiring layers 24 are formed of a metal such as copper. The stacked wiring layers 24 are electrically connected to each other by via conductors 26 at predetermined locations. The fabrication method of the wiring substrate 20, which is not specifically defined or limited herein, may be a known buildup process, for instance. Also, the wiring substrate 20 may be a so-called coreless substrate, which can be obtained by constructing a multilayer wiring on a metal-sheet base and then removing the metal sheet. Also, the wiring substrate 20 may be formed by stacking prepregs each having a wiring layer.

The wiring substrate 20 has a recess 28 formed therein. The depth of the recess 28 is practically the same as the sum of the thickness of the semiconductor element 30 to be discussed later and the thickness of a bonding layer 32. The substrate electrodes 40 are provided on the surface other than the recess 28 of the wiring substrate 20, that is, on the surface thereof surrounding the recess 28. The substrate electrodes 40 are formed of copper or gold, for instance. The height of the surface of the substrate electrodes 40 is approximately equal to the height of the surface of the element electrodes 50 to be discussed later.

An insulating layer 70 having openings for the substrate electrodes 40 is formed on the upper surface of the wiring substrate 20. The insulating layer 70 is formed of a material that develops plastic flow under pressure. A material that develops plastic flow under pressure may be an epoxy thermosetting resin, for instance. The epoxy thermosetting resin to be used for the insulating layer 70 may preferably have, for example, a viscosity of about 1 kPa·s at a temperature of 160° C. and a pressure of 8 MPa. When placed under a pressure of 15 MPa at a temperature of 160° C., the viscosity of this resin material drops to about ⅛ of that without the pressurization.

On the other hand, a photo solder resist layer 80 is formed on the lower surface of the wiring substrate 20 in such a manner that part of the lowermost wiring layer 24 opens therethrough. And solder balls 90 are formed as external electrodes in the openings for the lowermost wiring layer 24. It is to be noted that as external electrodes, solder bumps, gold bumps, copper bumps or the like may be used instead of the solder balls.

The semiconductor element 30 is a semiconductor chip of LSI (Large Scale Integration) or the like. The semiconductor element 30 is embedded in the recess 28 formed in the wiring substrate 20. An electrode-forming face (surface) of the semiconductor element 30 faces upwards in FIG. 1, whereas the back face of the semiconductor element 30 faces the bottom surface of the recess 28. The back face of the semiconductor element 30 is fixed to the bottom surface of the recess 28 by the bonding layer 32 such as die-attach film. The element electrodes 50 are provided on the electrode-forming face of the semiconductor element 30. The element electrodes 50 are formed of aluminum or copper, for instance. Note that the gaps between side faces of the semiconductor element 30 and side faces of the recess 28 are preferably filled with the insulating layer 70. Such an arrangement can improve the fixedness and adhesion of the semiconductor element 30 within the recess 28.

The wiring 60 includes a wiring layer 64 formed integrally with bumps 62a for connection with substrate electrodes 40 and bumps 62b for connection with element electrodes 50. The thickness of the wiring layer 64 may be 30 μm, for instance. This represents a markedly smaller thickness in comparison with the wire loop in wire bonding. As the wiring layer 64, a rolled copper is used suitably. Compared with a metal film of copper formed by plating or the like, the rolled copper excels as a material for rewiring because it has a greater mechanical strength. The bonding of the substrate electrodes 40 with the bumps 62a and the bonding of the element electrodes 50 with the bumps 62b are accomplished, for example, by performing a heated press-bonding of the wiring 60 against the wiring substrate 20 through the medium of the insulating layer 70, thereby having the bumps 62a and the bumps 62b penetrate the insulating layer 70. It is to be noted that having the height of the surface of the substrate electrodes 40 approximately equal to the height of the surface of the element electrodes 50 and having the height of the bump 62a practically equal to that of the bump 62b improves the accuracy of electrode connection. This is because such an arrangement makes it possible to bond the substrate electrodes 40 with the bumps 62a and the element electrodes 50 with the bumps 62b.

By implementing the structure as described above, the element electrodes 50 provided on the semiconductor element 30 embedded in the recess 28 in the wiring substrate 20 and the substrate electrodes 40 provided on the wiring substrate 20 are electrically connected with each other by the bumps 62b and the bumps 62a formed integrally with the wiring 60. The wiring 60, which does not require as much thickness as wire bonding, makes it possible to form a thinner semiconductor module 10. Also, the wiring 60 works to reduce the manufacturing cost of the semiconductor module because the wiring 60 can be formed by etching and heated press-bonding of a metal sheet without the use of laser processing or plating. Furthermore, the wiring layer 64 integrally formed with the bumps 62a and 62b can realize a semiconductor module 10 that features low resistance and high reliability.

(Manufacturing Method of Semiconductor Module)

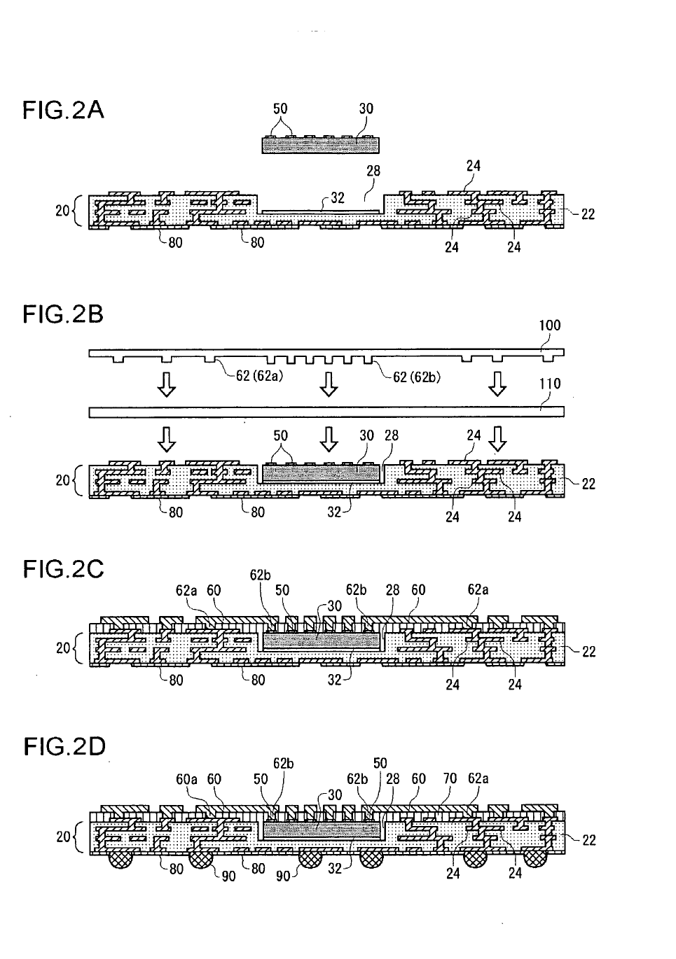

Referring to FIG. 2, a description will now be given of a method for manufacturing a semiconductor module according to the first embodiment of the present invention.

First, as shown in FIG. 2A, a wiring substrate 20, which has a multilayer wiring structure with a plurality of wiring layers 24 stacked through the medium of an insulating layer 22 and a recess 28 formed in one of the faces thereof, is prepared. The recess 28 may be formed either by stacking one or more prepregs with a hole opened in the area corresponding to the recess 28 or by mechanically processing a substrate with wiring completed therein. It is preferable that the wiring substrate 20 has two or more wiring layers 24, and it is further preferable that part of the wiring layers 24 is exposed on both faces of the wiring substrate 20. In the preferred embodiment of the present manufacturing method, a photo solder resist layer 80 is selectively formed in such a manner that part of the wiring layer 24 is exposed on the back face the wiring substrate 20.

Then, as also shown in FIG. 2A, a semiconductor element 30, such as an LSI with element electrodes 50 formed thereon, is fixed within the recess 28 using a bonding layer 32 of die-attach film or the like. Here, it is desirable that in order to carry out subsequent electrode connection with accuracy, the depth of the recess 28 and the thickness of the semiconductor element 30 are so adjusted that the wiring layer 24 provided on the surface of the wiring substrate 20 other than the recess 28, namely the surface thereof around the recess 28 is approximately on the same plane as the element electrodes 50 provided on the surface of the semiconductor element 30. For example, when the thickness of the semiconductor element 30 is 100 μm and the thickness of the bonding layer 32 is 25 μm, the depth of the recess 28 may be about 125 μm.

Next, as shown in FIG. 2B, a metal sheet 100 with bumps (projections) 62 formed thereon is prepared. Note that the bumps 62 is comprised of bumps 62a and bumps 62b which correspond to substrate electrodes 40 on the wiring substrate 20 and element electrodes 50 on the semiconductor element 30, respectively. The metal sheet 100 is preferably a rolled copper about 10 to 100 μm thick, for instance. Also, the height of the bumps 62 may be in the range of 10 to 50 μm, and may typically be 35 μm. Also, the diameter of each of the bumps 62 may be in the range of 10 to 100 μm, and may typically be 50 μm. The bumps 62 may be formed preferably by wet-etching a copper sheet with ferric chloride or the like. Such a process can form the bumps 62 integrally with the wiring layer, thus realizing a wiring that features low resistance and high reliability.

Then, as also shown in FIG. 2B, the metal sheet 100 with the bumps 62 formed thereon is superposed on the wiring substrate 20 carrying the semiconductor element 30 in the recess 28 therein via a resin sheet 110 for bonding, and then they are subjected to a heated press-bonding together. As a result of this process, the element electrodes 50 formed on the surface of the semiconductor element 30 and the substrate electrodes, which are the predetermined positions of the wiring layer 24 formed on the upper face of the wiring substrate 20, are electrically connected with each other by the corresponding bumps 62 provided on the metal sheet 100. Here, the material for the resin sheet 110 may preferably be a resin that develops plastic flow under pressure. The thickness of the resin sheet 110 is set nearly equal to the height of the bumps 62. The thermocompression bonding is done at a temperature of 200° C. and a pressure of 5 MPa, for instance.

Next, as shown in FIG. 2C, a rewiring pattern, namely, a wiring 60, is formed by etching the back face (upper face in FIG. 2C) of the metal sheet 100.

Then, as shown in FIG. 2D, solder balls 90 as external connection terminals are mounted by screen printing or the like on the exposed portions of the wiring layer 24 on the underside of the wiring substrate 20.

A semiconductor module is thus manufactured through the processes as described above.

The present invention is not limited to the above-described embodiment only, and it is understood by those skilled in the art that various modifications such as changes in design may be made based on their knowledge and the embodiments added with such modifications are also within the scope of the present invention.

For example, according to the first embodiment, a photo solder resist layer 80 is formed in advance on the underside of the wiring substrate 20, as illustrated in FIG. 2A. However, the photo solder resist layer 80 may be formed after the heated press-bonding which takes place in FIG. 2B. Also, the bonding layer 32, which is provided on a wiring substrate side, may be provided on the underside of the semiconductor element 30.

### SECOND EMBODIMENT

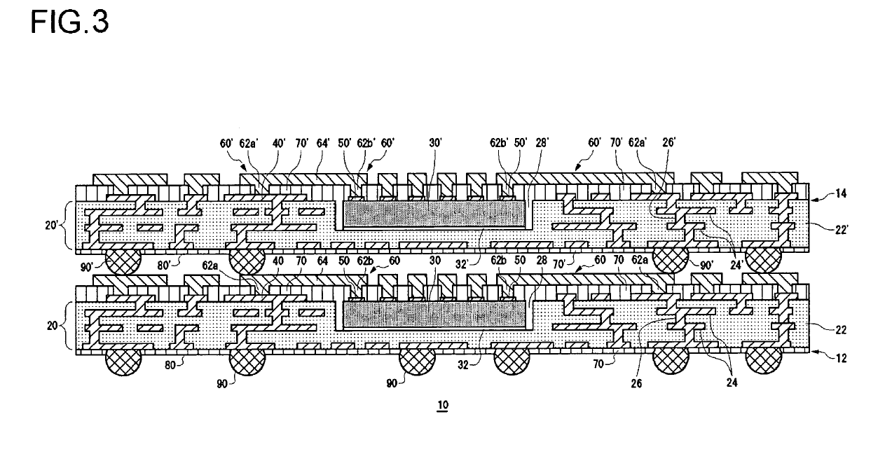

FIG. 3 is a schematic cross-sectional view illustrating a structure of a semiconductor apparatus 500 according to a second embodiment of the present invention. The semiconductor apparatus 500 according to the second embodiment has a packaged structure of a semiconductor module 14 stacked on top of a semiconductor module 12. The semiconductor module 14 has a packaged structure identical to that of the semiconductor module 12. Hence, in FIG. 3, the structure of the semiconductor module 14 is shown with reference numerals identical to those of the semiconductor module 12, with an apostrophe (') added thereto, and the description thereof will be omitted as appropriate. The semiconductor module 12 includes, as principal components, a wiring substrate 20, a semiconductor element 30, substrate electrodes 40, element electrodes 50, and a wiring 60.

The wiring substrate 20 has a multilayer wiring structure with a plurality of wiring layers 24 stacked through the medium of an insulating layer 22. The insulating layer 22 may be made of, for example, a melamine derivative, such as BT resin, or a thermosetting resin, such as liquid-crystal polymer, epoxy resin, polyphenylene ether (PPE) resin, polyimide resin, fluorine resin, phenol resin, or polyamide bismaleimide. The wiring layers 24 are formed of a metal such as copper. The stacked wiring layers 24 are electrically connected to each other by via conductors 26 at predetermined points. The fabrication method of the wiring substrate 20, which is not specifically defined or limited herein, may be a known buildup process, for instance. Also, the wiring substrate 20 may be a so-called coreless substrate, which can be obtained by constructing a multilayer wiring on a metal-sheet base and then removing the metal sheet. Also, the wiring substrate 20 may be formed by stacking prepregs each having a wiring layer.

The wiring substrate 20 has a recess 28 formed therein. The depth of the recess 28 is practically the same as the sum of the thickness of the semiconductor element 30 to be discussed later and the thickness of a bonding layer 32. The substrate electrodes 40 are provided on the surface other than the recess 28 of the wiring substrate 20, that is, on the surface thereof surrounding the recess 28. The substrate electrodes 40 are formed of copper or gold, for instance. The height of the surface of the substrate electrodes 40 is approximately equal to the height of the surface of the element electrodes 50 to be discussed later.

An insulating layer 70 having openings for the substrate electrodes 40 is formed on the upper surface of the wiring substrate 20. The insulating layer 70 is formed of a material that develops plastic flow under pressure. A material that develops plastic flow under pressure may be an epoxy thermosetting resin, for instance. The epoxy thermosetting resin to be used for the insulating layer 70 may preferably have, for example, a viscosity of about 1 kPa·s at a temperature of 160° C. and a pressure of 8 MPa. When placed under a pressure of 15 MPa at a temperature of 160° C., the viscosity of this resin material drops to about ⅛ of that without the pressurization.

On the other hand, a photo solder resist layer 80 is formed on the lower surface of the wiring substrate 20 in such a manner that part of the lowermost wiring layer 24 opens therethrough. And solder balls 90 are formed as external electrodes in the openings for the lowermost wiring layer 24. It is to be noted that as external electrodes, solder bumps, gold bumps, copper bumps, or the like may be used instead of the solder balls.

The semiconductor element 30 is a semiconductor chip of LSI (Large Scale Integration) or the like. The semiconductor element 30 is embedded in the recess 28 formed in the wiring substrate 20. The electrode-forming face (surface) of the semiconductor element 30 faces upwards in FIG. 3, whereas the back face of the semiconductor element 30 faces the bottom surface of the recess 28. The back face of the semiconductor element 30 is fixed to the bottom surface of the recess 28 by the bonding layer 32 such as die-attach film. The element electrodes 50 are provided on the electrode-forming face of the semiconductor element 30. The element electrodes 50 are formed of aluminum or copper, for instance. Note that the gaps between side faces of the semiconductor element 30 and side faces of the recess 28 are preferably filled with the insulating layer 70. Such an arrangement can improve the fixedness and adhesion of the semiconductor element 30 within the recess 28.

The wiring 60 includes a wiring layer 64 formed integrally with bumps 62a for connection with substrate electrodes 40 and bumps 62b for connection with element electrodes 50. The thickness of the wiring layer 64 may be 30 μm, for instance. This represents a markedly smaller thickness in comparison with the wire loop in wire bonding. As the wiring layer 64, a rolled copper is used suitably. Compared with a metal film of copper formed by plating or the like, the rolled copper excels as a material for rewiring because it has a greater mechanical strength. The bonding of the substrate electrodes 40 with the bumps 62a and the bonding of the element electrodes 50 with the bumps 62b are accomplished, for example, by performing a heated press-bonding of the wiring 60 against the wiring substrate 20 through the medium of the insulating layer 70, thereby having the bumps 62a and the bumps 62b penetrate the insulating layer 70. It is to be noted that having the height of the surface of the substrate electrodes 40 approximately equal to the height of the surface of the element electrodes 50 and having the height of the bump 62a practically equal to that of the bump 62b improves the accuracy of electrode connection. This is because such an arrangement makes it possible to bond the substrate electrodes 40 with the bumps 62a and the element electrodes 50 with the bumps 62b.

Note also it is only necessary that an upper part of the wiring 60 is at least exposed in connection regions where solder balls 90′ of the semiconductor module 14 are connected, and therefore the parts other than the connection regions thereof may be covered with an insulating resin layer such as a photo solder resist.

The solder balls 90′ provided on the semiconductor module 14 are connected to the top surface of the wiring 60. This forms a stacked structure of the semiconductor module 12 and the semiconductor module 14. It is to be noted that a gold plating layer (Au/Ni plating layer) may be interposed between the wiring 60 and the solder balls 90′. An arrangement like this can improve the corrosion resistance of the wiring 60.

By implementing the structure as described above, the element electrodes 50 provided on the semiconductor element 30 embedded in the recess 28 in the wiring substrate 20 and the substrate electrodes 40 provided on the wiring substrate 20 are electrically connected with each other by the bumps 62b and the bumps 62a formed integrally with the wiring 60. The wiring 60, which does not require as much thickness as wire bonding, makes it possible to form a thinner semiconductor module 12. Also, the wiring 60 works to reduce the manufacturing cost of the semiconductor module because the wiring 60 can be formed by etching and heated press-bonding of a metal sheet without the use of laser processing or plating. Furthermore, the wiring layer 64 integrally formed with the bumps 62a and 62b can realize a semiconductor module 12 that features low resistance and high reliability. These advantageous effects also apply to the semiconductor module 14, and the stacking of the semiconductor module 12 and the semiconductor module 14 realizes a thinner and lower-cost production of semiconductor apparatuses.

Also, the solder balls 90′ can be made smaller because the top surface of the semiconductor module 12 can be flattened. In other words, the gap between the semiconductor module 12 and the semiconductor module 14 can be made smaller, which makes the semiconductor apparatus as a whole thinner.

(Manufacturing Method of Semiconductor Apparatus)

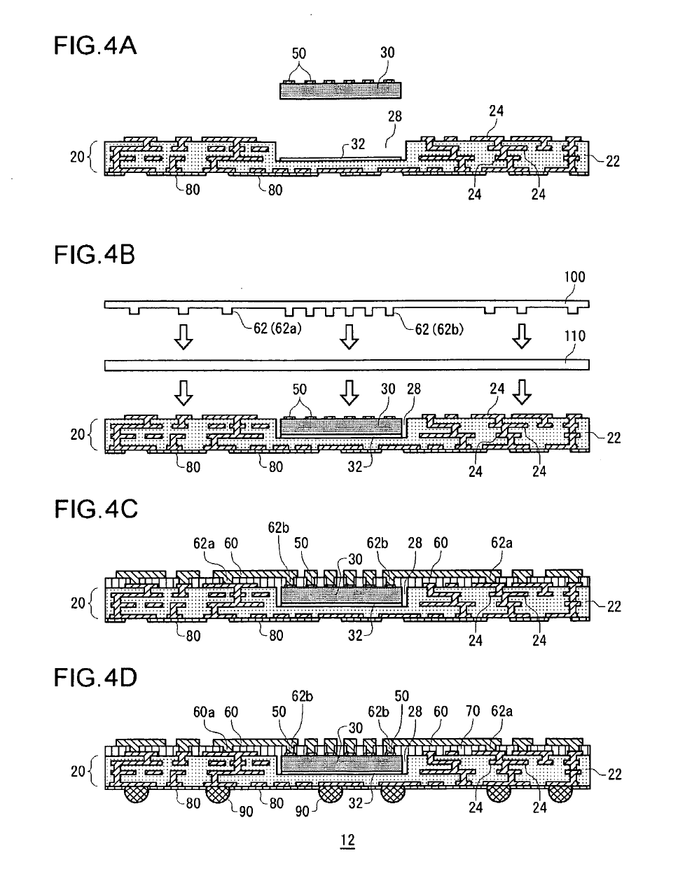

Referring to FIG. 4, a description will now be given of a method for manufacturing a semiconductor module according to the second embodiment of the present invention.

First, as shown in FIG. 4A, a wiring substrate 20, which has a multilayer wiring structure with a plurality of wiring layers 24 stacked through the medium of an insulating layer 22 and a recess 28 formed in one of the faces thereof, is prepared. The recess 28 may be formed either by stacking one or more prepregs with a hole opened in the area corresponding to the recess 28 or by mechanically processing a substrate with wiring completed therein. It is preferable that the wiring substrate 20 has two or more wiring layers 24, and it is further preferable that part of the wiring layers 24 is exposed on both faces of the wiring substrate 20. In the preferred embodiment of the present manufacturing method, a photo solder resist layer 80 is selectively formed in such a manner that part of the wiring layer 24 is exposed on the back face the wiring substrate 20.

Then, as also shown in FIG. 4A, a semiconductor element 30, such as an LSI with element electrodes 50 formed thereon, is fixed within the recess 28 using a bonding layer 32 of die-attach film or the like. Here, it is desirable that in order to carry out subsequent electrode connection with accuracy, the depth of the recess 28 and the thickness of the semiconductor element 30 are so adjusted that the wiring layer 24 provided on the surface of the wiring substrate 20 other than the recess 28, namely the surface thereof around the recess 28 is approximately on the same plane as the element electrodes 50 provided on the surface of the semiconductor element 30. For example, when the thickness of the semiconductor element 30 is 100 μm and the thickness of the bonding layer 32 is 25 μm, the depth of the recess 28 may be about 125 μm.

Next, as shown in FIG. 4B, a metal sheet 100 with bumps (projections) 62 formed thereon is prepared. Note that the bumps 62 is comprised of bumps 62a and bumps 62b which correspond to substrate electrodes 40 on the wiring substrate 20 and element electrodes 50 on the semiconductor element 30, respectively. The metal sheet 100 is preferably a rolled copper about 10 to 100 μm thick, for instance. Also, the height of the bumps 62 may be in the range of 10 to 50 μm, and may typically be 35 μm. Also, the diameter of each of the bumps 62 may be in the range of 10 to 100 μm, and may typically be 50 μm. The bumps 62 may be formed preferably by wet-etching a copper sheet with ferric chloride or the like. Such a process can form the bumps 62 integrally with the wiring layer, thus realizing a wiring that features low resistance and high reliability.

Then, as also shown in FIG. 4B, the metal sheet 100 with the bumps 62 formed thereon is superposed on the wiring substrate 20 carrying the semiconductor element 30 in the recess 28 therein via a resin sheet 110 for bonding, and then they are subjected to a heated press-bonding together. As a result of this process, the element electrodes 50 formed on the surface of the semiconductor element 30 and the substrate electrodes, which are the predetermined positions of the wiring layer 24 formed on the upper face of the wiring substrate 20, are electrically connected with each other by the corresponding bumps 62 provided on the metal sheet 100. Here, the material for the resin sheet 110 may preferably be a resin that develops plastic flow under pressure. The thickness of the resin sheet 110 is set nearly equal to the height of the bumps 62. The thermocompression bonding is done at a temperature of 200° C. and a pressure of 5 MPa, for example. In order to improve the connection reliability of the electrodes and the bumps, a film of Au, Au/Ni or Sn may be formed on the tip ends of the bumps, or a film of Au, Au/Ni or Sn may be formed on the surfaces of the electrodes.

Next, as shown in FIG. 4C, a rewiring pattern, namely, a wiring 60, is formed by etching the back face (upper face in FIG. 2C) of the metal sheet 100.

Then, as shown in FIG. 4D, solder balls 90 as external connection terminals are mounted by screen printing or the like on the exposed portions of the wiring layer 24 on the underside of the wiring substrate 20.

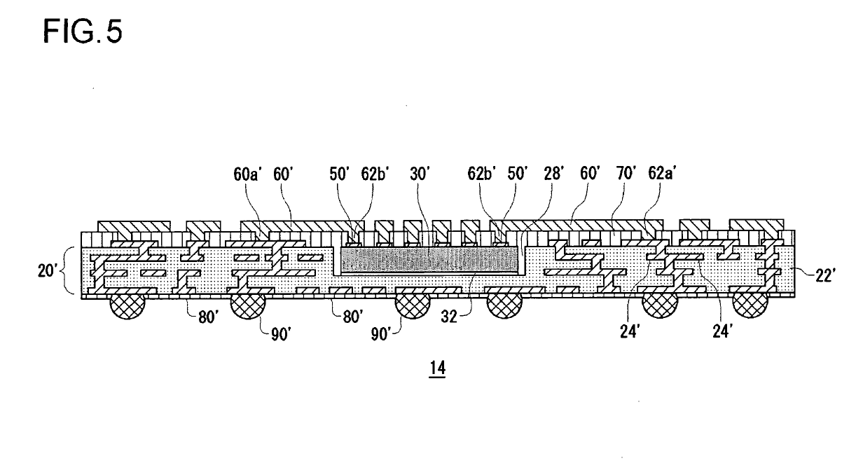

The semiconductor module 12 is thus manufactured through the processes as described above. Likewise, the semiconductor module 14 as shown in FIG. 5 is prepared using similar processes. Note that the positions where the solder balls 90′ of the semiconductor module 14 are mounted correspond to the connection regions of the wiring 60 on the semiconductor module 12.

Following this, the solder balls 90′ are bonded to the connection regions (exposed surfaces) of the wiring 60 on the semiconductor module 12 by use of a reflow process or the like. Thus, a semiconductor apparatus 500 having a packaged structure stacking the semiconductor module 14 on top of the semiconductor module 12, as shown in FIG. 3, is manufactured.

The present invention is not limited to the above-described embodiments only, and it is understood by those skilled in the art that various modifications such as changes in design may be made based on their knowledge and the embodiments added with such modifications are also within the scope of the present invention.

For example, according to the second embodiment, a photo solder resist layer 80 is formed in advance on the underside of the wiring substrate 20, as illustrated in FIG. 4A. However, the photo solder resist layer 80 may be formed after the heated press-bonding which takes place in FIG. 4B. Also, the bonding layer 32, which is provided on the wiring substrate, may be provided on the underside of the semiconductor element 30.

Also, the semiconductor apparatus according to the second embodiment as shown in FIG. 3 has two semiconductor modules stacked one in top of the other. However, a structure stacking three or more semiconductor modules is also feasible.

Also, the semiconductor apparatus according to the second embodiment as shown in FIG. 3 has a space (gap) between the semiconductor module 12 and the semiconductor module 14. However, an insulating material may be filled in the gap between the semiconductor module 12 and the semiconductor module 14. Such an arrangement allows the insulating material to protect the connections between the semiconductor module 12 and the semiconductor module 14, thus improving the connection reliability therebetween. Furthermore, another wiring layer may be formed on the wiring 60. This other wiring layer may be formed by a method similar to the one used for the wiring 60 or by a known buildup process or the like. Such a modification increases the freedom of layout of the solder balls 90′ which connect an upper and a lower semiconductor module, thus making the connection thereof easier.

Next, a description will be given of a mobile equipment or portable device provided with the above-described semiconductor module. The mobile device presented as an example herein is a mobile phone, but it may be any electronic apparatus, such as a personal digital assistant (PDA), a digital video cameras (DVC) and a digital still camera (DSC).

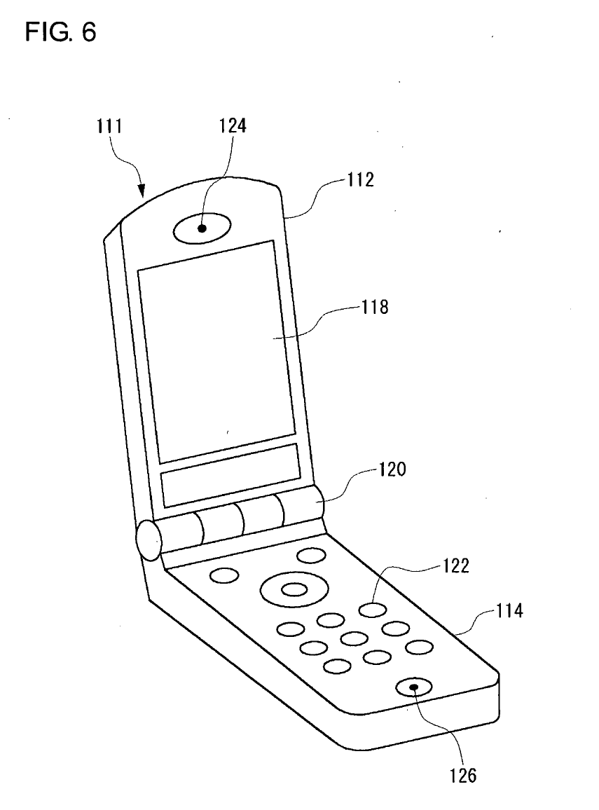

FIG. 6 illustrates a structure of a mobile phone provided with a semiconductor apparatus according to an embodiment of the present invention. A mobile phone 111 has a structure including a first casing 112 and a second casing 114 jointed together by a movable part 120. The first casing 112 and the second casing 114 are turnable/rotatable around the movable part 120 as the axis. The first casing 112 is provided with a display unit 118 for displaying characters, images and other information and a speaker unit 124. The second casing 114 is provided with a control module 122 with operation buttons and the like and a microphone 126. Note that a semiconductor apparatus according to the above-described embodiments is mounted within a mobile phone 111 such as this.

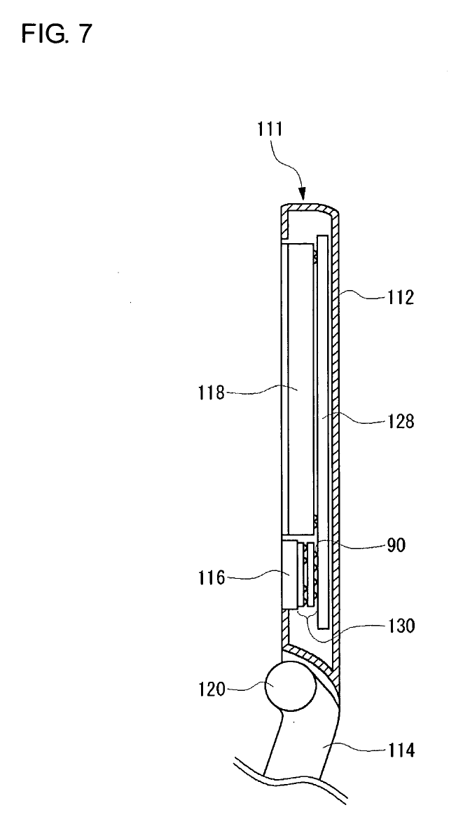

FIG. 7 is a partial cross-sectional view (cross-sectional view of the first casing 112) of the mobile phone shown in FIG. 6. A semiconductor apparatus 130 according to the embodiments is mounted on a printed circuit board 128 via solder balls 90, and is coupled electrically to a display unit 118 and the like by way of the printed circuit board 128. Also, a radiating substrate 216, such as a metal substrate, is provided on the back side of the semiconductor apparatus 130 (opposite side of the solder balls 90), so that the heat generated from the semiconductor apparatus 130, for example, can be efficiently released outside the first casing 112 without getting trapped therein.

The following advantageous effects are presented by a mobile device incorporating a semiconductor apparatus according to the preferred embodiments of the present invention:

(1) The reliability (heat resistance reliability) of a semiconductor apparatus 130 is improved because the separation of the wiring section within the semiconductor apparatus 130 from the insulating layer due to the thermal stress occurring during the operation of the semiconductor apparatus 130 is prevented. Thus, the reliability (heat resistance reliability) of a mobile device incorporating such a semiconductor apparatus 130 is also improved.

(2) Since the heat from the semiconductor apparatus 130 is released efficiently to the exterior through a radiating substrate 116, the temperature rise of the semiconductor apparatus 130 is suppressed, and the thermal stress between the wiring and the insulating layer is reduced. As a result, compared with the case without the radiating substrate 116, the separation of the wiring within the semiconductor apparatus from the insulating layer is prevented more effectively. Thus, the reliability (heat resistance reliability) of the semiconductor apparatus 130 is improved, and consequently, the reliability (heat resistance reliability) of a mobile device incorporating such a semiconductor apparatus 130 can also be improved.

(3) The semiconductor apparatus 130 is thinner and smaller, so that the mobile device incorporating such semiconductor apparatuses 130 can be made thinner and smaller.

While the preferred embodiments of the present invention have been described using specific terms, such description is for illustrative purposes only, and it is to be understood that changes and variations may be made without departing from the spirit or scope of the appended claims.

What is claimed is:

1. A semiconductor module, comprising:
a wiring substrate;
a semiconductor element placed in a recess formed in said wiring substrate;
a substrate electrode provided around the recess in said wiring substrate;
an element electrode provided on said semiconductor element opposite to a bottom of the recess; and
a wiring having a wiring layer integrally formed with a conductive bump for electrically connecting said substrate electrode to said element electrode.

2. A semiconductor module according to claim 1, wherein a material used for said wiring is a rolled copper sheet.

3. A semiconductor module according to claim 1, wherein the height of said element electrode is approximately equal to the height of said substrate electrode.

4. A semiconductor module according to claim 2, wherein the height of said element electrode is approximately equal to the height of said substrate electrode.

5. A semiconductor module according to claim 1, wherein an insulating resin that develops plastic flow under pressure is provided between said wiring substrate and said wiring.

6. A semiconductor module according to claim 2, wherein an insulating resin that develops plastic flow under pressure is provided between said wiring substrate and said wiring.

7. A semiconductor module according to claim 3, wherein an insulating resin that develops plastic flow under pressure is provided between said wiring substrate and said wiring.

8. A method for manufacturing a semiconductor module, the method comprising:
placing a semiconductor element into a recess provided in a wiring substrate; and
electrically connecting substrate electrode provided on a surface of the wiring substrate around the recess and element electrode provided on a surface of the semiconductor element by use a wiring including a wiring layer integrally formed with conductive bumps corresponding respectively to the substrate electrode and the element electrode.

9. A method, for manufacturing a semiconductor module, according to claim 8, wherein, in said electrically connecting substrate electrode and element electrode by use of the wiring, the bumps included in the wiring are connected respectively to the substrate electrode and the element electrode by thermocompression bonding the wiring through an insulating layer that develops plastic flow under pressure.

10. A semiconductor apparatus having a plurality of semiconductor modules stacked together, at least one of the plurality of semiconductor modules comprising:
a wiring substrate;
a semiconductor element placed in a recess formed in said wiring substrate;
a substrate electrode provided around the recess in said wiring substrate;
an element electrode provided on said semiconductor element opposite to a bottom of the recess; and
a wiring having a wiring layer integrally formed with a conductive bump for electrically connecting said substrate electrode to said element electrode.

11. A semiconductor apparatus according to claim 10, having a pair of upper and lower semiconductor modules stacked on each other, wherein the upper semiconductor module has an external electrode formed under said wiring substrate, and
wherein the external electrode is electrically connected to the wiring of the lower semiconductor module.

12. A semiconductor apparatus according to claim 10, wherein for each of the plurality of semiconductor modules a material used for said wiring is a rolled copper sheet.

13. A semiconductor apparatus according to claim 11, wherein for each of the plurality of semiconductor modules a material used for said wiring is a rolled copper sheet.

14. A semiconductor apparatus according to claim 10, wherein for each of the plurality of semiconductor modules the height of said element electrode is approximately equal to the height of said substrate electrode.

15. A semiconductor apparatus according to claim 11, wherein for each of the plurality of semiconductor modules the height of said element electrode is approximately equal to the height of said substrate electrode.

16. A semiconductor apparatus according to claim 10, wherein for each of the plurality of semiconductor modules an insulating resin that develops plastic flow under pressure is provided between said wiring substrate and said wiring.

17. A semiconductor apparatus according to claim 11, wherein for each of the plurality of semiconductor modules an insulating resin that develops plastic flow under pressure is provided between said wiring substrate and said wiring.

18. A method for manufacturing a semiconductor apparatus, the method comprising:
forming a semiconductor module; and
stacking a plurality of semiconductor modules including said semiconductor module formed in said forming a semiconductor apparatus,
said forming a semiconductor module including:
placing a semiconductor element into a recess provided in a wiring substrate; and
electrically connecting substrate electrode provided on a surface of the wiring substrate around the recess and element electrode provided on a surface of the semiconductor element by use a wiring including a wiring layer integrally formed with conductive bumps corresponding respectively to the substrate electrode and the element electrode.

19. A method, for manufacturing a semiconductor apparatus, according to claim 18, wherein, in said electrically connecting substrate electrode and element electrode by use of the wiring, the bumps included in the wiring are connected respectively to the substrate electrode and the element electrode by thermocompression bonding the wiring through an insulating layer that develops plastic flow under pressure.

20. A portable device, including a semiconductor module according to claim 10.
